(19) United States
(12) Patent Application Publication
(10) Pub. No.: US 2026/0298988 A1
(43) Pub. Date: Oct. 1, 2026

(54) WINDING SWITCHING DEVICE AND WINDING SWITCHING SYSTEM

(71) Applicants: Sumitomo Electric Industries, Ltd., Osaka-Shi, Osaka (JP); Sumitomo Wiring Systems, Ltd., Yokkaichi-Shi, Mie (JP); AutoNetworks Technologies, Ltd., Yokkaichi-Shi, Mie (JP)

(72) Inventor: Masaki TSUDA, Osaka-Shi, Osaka (JP)

(73) Assignees: Sumitomo Electric Industries, Ltd., Osaka-Shi, Osaka (JP); Sumitomo Wiring Systems, Ltd., Yokkaichi-Shi, Mie (JP); AutoNetworks Technologies, Ltd., Yokkaichi-Shi, Mie (JP)

(21) Appl. No.: 18/881,356

(22) PCT Filed: Mar. 3, 2023
(86) PCT No.: PCT/JP2023/008040

§ 371 Date: Jan. 6, 2025

(30) Foreign Application Priority Data
Jul. 6, 2022 (JP) 2022-109213

(51) Int. Cl. G01R 19/175; G01R 19/165; H02P 25/18; H02P 25/22; H02P 27/08

(52) U.S. Cl. CPC G01R 19/175; G01R 19/1658; H02P 25/18; H02P 25/22; H02P 27/08; H02P 2207/05

(57) ABSTRACT

A winding switching device is a winding switching device for switching a connection state of a plurality of windings of a motor capable of switching the connection state of the plurality of windings between a first connection state and a second connection state, and includes: a detection unit that detects a zero crossing point of a measurement value of a current sensor that measures current flowing through a winding of the windings, and a switching unit that switches the connection state of the plurality of windings between the first connection state and the second connection state at a timing when the detection unit detects the zero crossing point.

### CROSS-REFERENCE TO RELATED APPLICATIONS

This application is the U.S. national stage of PCT/JP2023/008040 filed on Mar. 3, 2023, which claims priority of Japanese Patent Application No. JP 2022-109213 filed on Jul. 6, 2022, the contents of which are incorporated herein.

### TECHNICAL FIELD

The present disclosure relates to a winding switching device and a winding switching system.

### BACKGROUND

Some motors mounted in, for example, electric vehicles are capable of switching between a low speed, high torque operating state and a high speed, low-torque operating state by switching connections of a plurality of windings. JP 2020-072632A discloses a device that specifies a period during which an AC motor current is less than or equal to a predetermined value and switches windings during the specified period in order to prevent a surge voltage.

The device disclosed in JP 2020-072632A uses a processor such as a microcomputer, a field-programmable gate array (FPGA) or an application-specific integrated circuit (ASIC) to specify a period during which a motor current is less than or equal to a predetermined value. However, the switching of the connection of the windings needs to be performed within a brief period of time on the order of several microseconds to sub-microseconds, and there is a possibility that program processing in a microcomputer will not be fast enough. On the other hand, although an FPGA or ASIC is capable of high-speed processing, there is a problem in that it is expensive.

### SUMMARY

A winding switching device according to an aspect of the present disclosure is a winding switching device for switching a connection state of a plurality of windings of a motor capable of switching the connection state of the plurality of windings between a first connection state and a second connection state, the winding switching device including: a detection unit configured to detect a zero crossing point of a measurement value of a current sensor configured to measure current flowing through a winding of the windings; and a switching unit configured to switch the connection state of the plurality of windings between the first connection state and the second connection state at a timing at which the detection unit detects the zero crossing point.

### Advantageous Effects of the Present Disclosure

According to the present disclosure, it is possible to suppress the occurrence of a surge voltage with an inexpensive configuration.

### BRIEF DESCRIPTION OF DRAWINGS

FIG. 1 is a diagram showing an example of a configuration of a winding switching system according to a first embodiment.

FIG. 2 is a circuit diagram showing an example of a configuration of a winding switching device according to the first embodiment.

FIG. 3 is a circuit diagram showing an example of a configuration of a control circuit.

FIG. 4 is a timing chart showing an example of transition of states of signals in the winding switching device according to the first embodiment.

FIG. 5 is a circuit diagram showing an example of a configuration of a winding switching device according to a second embodiment.

FIG. 6 is a circuit diagram showing an example of a configuration of a winding switching device according to a third embodiment.

FIG. 7 is a circuit diagram illustrating an example of a configuration of a correction circuit.

FIG. 8A is a graph showing waveforms of a voltage signal from a current sensor and a voltage signal from a filter.

FIG. 8B is a graph showing a waveform of a voltage signal from a subtraction circuit.

FIG. 9 is a circuit diagram showing a modified example of the configuration of the winding switching device according to the third embodiment.

FIG. 10 is a circuit diagram showing an example of a configuration of a winding switching device according to a fourth embodiment.

### DETAILED DESCRIPTION OF PREFERRED EMBODIMENTS

Hereinafter, an overview of embodiments of the present disclosure will be listed and described.
(1) A winding switching device according to the present embodiment is a winding switching device for switching a connection state of a plurality of windings of a motor capable of switching the connection state of the plurality of windings between a first connection state and a second connection state, the winding switching device including: a detection unit configured to detect a zero crossing point of a measurement value of a current sensor configured to measure current flowing through a winding of the windings; and a switching unit configured to switch the connection state of the plurality of windings between the first connection state and the second connection state at a timing at which the detection unit detects the zero crossing point. This eliminates the need for complex processing such as specifying a period during which a motor current is less than or equal to a predetermined value. Accordingly, the configuration of the detection unit can be simplified, and the occurrence of a surge voltage can be suppressed with an inexpensive configuration.
(2) In (1) above, the motor may be a multi phase AC motor, the detection unit may detect the zero crossing point for each phase, and the switching unit may switch the connection state of the plurality of windings between the first connection state and the second connection state for each phase. This allows the connection state of the windings to be switched at the zero crossing point for each phase, making it possible to suppress the occurrence of a surge voltage in each phase.
(3) In (1) or (2) above, the detection unit may compare an output voltage from the current sensor and a reference voltage corresponding to the output voltage of the current sensor when the current flowing through the winding is zero, and may detect, as a zero crossing point, a point in time when the output voltage from the current sensor and the reference voltage coincide with each other. This allows the detection unit to perform simple processing for comparing the output voltage from the current sensor with the reference voltage, thereby simplifying the configuration of the detection unit.
(4) In (3) above, the detection unit may be a comparator. This allows the detection unit to be constituted by an inexpensive comparator.
(5) In any one of (1) to (4) above, the detection unit may share the current sensor with control of a power converter configured to convert a DC voltage output from a battery into an AC voltage and supply the AC power to the motor. This allows the number of current sensors in the entire system to be reduced, resulting in a more inexpensive configuration.
(6) In (5) above, the current sensor may be disposed in the winding switching device. This makes it possible for the winding switching device alone to measure the current flowing through the windings and detect the zero crossing points.
(7) In (6) above, the current sensor may be an AC current transformer. If the only purpose is to detect the zero crossing point of the winding current, an AC current transformer (ACCT) that can measure only the AC component of the current can be used. Thus, the occurrence of a surge voltage can be suppressed with an inexpensive configuration.
(8) In (5) above, the current sensor may be disposed in the power converter, and a signal line extending from the current sensor may be connected to the detection unit. This makes it possible to detect the zero crossing point of the winding current by using a current sensor provided in the power converter.
(9) In (8) above, the winding switching device may further include a correction unit configured to remove a DC component from the output signal of the current sensor, and the detection unit may detect a zero crossing point of the output signal of the current sensor from which the DC component has been removed by the correction unit. This makes it possible to remove the DC component from the output signal of the current sensor and accurately detect the zero crossing point.
(10) A winding switching system according to the present embodiment includes: a motor capable of switching a connection state of a plurality of windings between a first connection state and a second connection state; a power converter configured to convert DC power output from a battery into AC power and supply the AC power to the motor; and a winding switching device for switching the connection state of the plurality of windings, in which the winding switching device includes a detection unit configured to detect a zero crossing point of a measurement value of a current sensor configured to measure current flowing through a winding of the windings; and a switching unit configured to switch the connection state of the plurality of windings between the first connection state and the second connection state at a timing when the detection unit detects the zero crossing point. This eliminates the need for complex processing such as specifying a period during which a motor current is less than or equal to a predetermined value. Accordingly, the configuration of the detection unit can be simplified, and the occurrence of a surge voltage can be suppressed with an inexpensive configuration.

The present disclosure can be realized not only as a winding switching device having the above-described characteristic configuration and a winding switching system including the winding switching device, but also as a winding switching method having steps corresponding to characteristic processing in the winding switching device, as a computer program for causing a computer to execute the characteristic processing, or as a semiconductor integrated circuit that realizes part or all of the winding switching device.

Hereinafter, details of the embodiments of the present invention will be described with reference to the drawings. Note that at least some of the embodiments described below may be combined in any manner.

### 1. First Embodiment

### 1-1. Winding Switching System

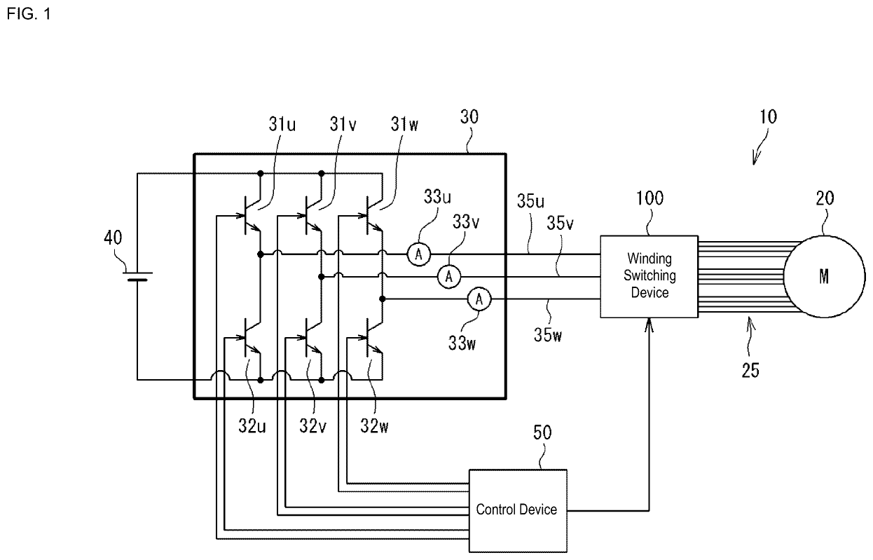

FIG. 1 is a diagram showing an example of a configuration of a winding switching system according to a first embodiment.

The winding switching system 10 is mounted in a vehicle propelled by a motor, such as an electric vehicle or a plug-in hybrid vehicle (hereinafter, referred to as an “electric vehicle”). The winding switching system 10 includes a motor 20, a power converter 30, a battery 40, a control device 50, and a winding switching device 100.

The motor 20 is a travel motor that generates propulsive force for the electric vehicle. The motor 20 is driven by three-phase AC power. An example of the motor 20 is a permanent magnet synchronous motor.

The battery 40 is a battery for supplying power to drive the motor 20. The battery 40 is a secondary battery, and is, for example, a lithium ion battery.

The power converter 30 is an inverter that converts DC power supplied from the battery 40 into three-phase AC power. The power converter 30 may have a function of converting the three-phase AC power output when the motor 20 functions as a generator into DC power and charging the battery 40.

The power converter 30 includes a leg for each of the U-phase, the V-phase, and the W-phase. The U-phase leg includes switches 31u and 32u, the V-phase leg includes switches 31v and 32v, and the W-phase leg includes switches 31w and 32w. The switches 31u, 32u, 31v, 32v, 31w, and 82w perform switching, whereby the DC power is converted into three-phase AC power. The switches 31u, 32u, 31v, 82v, 31w, and 32w are, for example, insulated gate bipolar transistors (IGBTs) or power metal oxide semiconductor field effect transistors (MOSFETs).

A power line 35u corresponding to the U-phase extends from the U-phase leg, a power line 35v corresponding to the V-phase extends from the V-phase leg, and a power line 35w corresponding to the W-phase extends from the W-phase leg. In the power converter 30, a current sensor 33u is provided on the power line 35u, a current sensor 33v is provided on the power line 35v, and a current sensor 33w is provided on the power line 35w. The current sensor 33u detects the current value of the U-phase current Iu. The current sensor 33v detects the current value of the V-phase current Iv. The current sensor 33w detects the current value of the W-phase current Iw. The current sensors 33u, 33v, and 33w can detect the current values as well as the DC and AC components of the currents Iu, Iv, and Iw flowing through the power lines 35u, 35v, and 35w. The current sensors 33u, 33v, and 33w are, for example, DC current transformers (DCCTs) or shunt resistors.

The winding switching device 100 is disposed between the motor 20 and the power converter 30. However, the location of the winding switching device 100 is not limited to between the motor 20 and the power converter 30. The power converter 30 and the winding switching device 100 are connected to each other by the power lines 35u, 35v, and 35w, and the winding switching device 100 and the motor 20 are connected to each other by a plurality of power lines 25. The winding switching device 100 switches the connection state of a plurality of windings of the motor 20. The configuration of the winding switching device 100 will be described later. Three-phase AC currents Iu, Iv, and Iw output from the power converter 30 are supplied to the motor 20 via the winding switching device 100.

The control device 50 controls the power converter 30 and the winding switching device 100. Specifically, signal lines extend from the control device 50 to each of the switches 31u, 32u, 31v, 32v, 31w, and 32w, and the control device 50 controls the on/off timing of the switches 31u, 32u, 31v, 32v, 31w, and 32w. A signal line extends from the control device 50 to the winding switching device 100, and the control device 50 outputs a switching command signal for commanding switching of the connection state of the windings to the winding switching device 100.

The control device 50 includes a processor, a memory, an input/output interface, a communication interface, and the like (not shown). The processor is, for example, a central processing unit (CPU). However, the processor is not limited to a CPU. The processor may be a graphics processing unit (GPU). The processor may be, for example, an application specific integrated circuit (ASIC) or a programmable logic device such as a gate array or a field programmable gate array (FPGA).

### 1-2. Configuration of Winding Switching Device

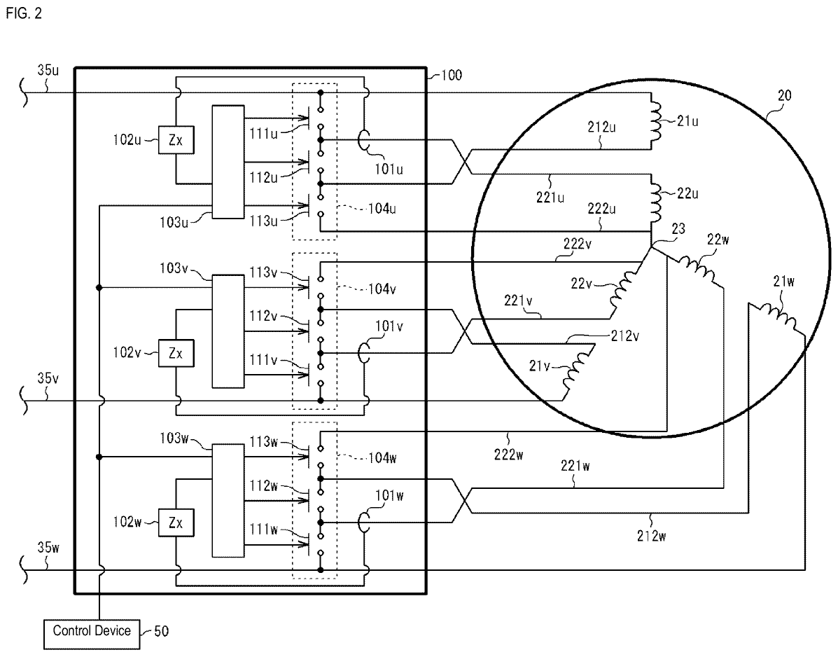

FIG. 2 is a circuit diagram showing an example of the configuration of the winding switching device according to the first embodiment. The motor 20 includes a plurality of windings 21u, 22u, 21v, 22v, 21w, and 22w. The windings 21u and 22u correspond to the U-phase, the windings 21v and 22v correspond to the V-phase, and the windings 21w and 22w correspond to the W-phase. However, the number of windings for each phase is not limited to two, and may be three or more. The windings 22u, 22v, and 22w are connected at a neutral point 23.

The winding switching device 100 switches the connection state of the windings 21u, 22u, 21v, 22v, 21w, and 22w for each phase between a series connection state and a parallel connection state. The winding switching device 100 includes current sensors 101u, 101v, and 101w, zero crossing detection circuits 102u, 102v, and 102w, control circuits 103u, 103v, and 103w, and switching circuits 104u, 104v, and 104w.

The zero crossing detection circuits 102u, 102v, and 102w detect zero crossing points of the measurement values of the current sensors 101u, 101v, and 101w. In a more specific example, the zero crossing detection circuits 102u, 102v, and 102w compare the output voltages from the current sensors 101u, 101v, and 101w with a zero voltage, and detect points in time when the output voltages from the current sensors 101u, 101v, and 101w coincide with the zero voltage as the zero crossing points. The zero voltage is an example of a reference voltage. The reference voltage is a voltage corresponding to the output voltages of the current sensors 101u, 101v, and 101w when the current flowing through the windings 21u, 22u, 21v, 22v, 21w, and 22w becomes zero, and is not limited to the zero voltage. The zero crossing detection circuits 102u, 102v, and 102w are examples of detection units.

The switching circuits 104u, 104v, and 104w switch the connection state of the windings 21u, 22u, 21v, 22v, 21w, and 22w between a series connection state and a parallel connection state at the timing when the zero crossing detection circuits 102u, 102v, and 102w detect the zero crossing points. The switching circuits 104u, 104v, and 104w are examples of switching units. The series connection state is an example of a first connection state, and the parallel connection state is an example of a second connection state.

Hereinafter, the connection relationship between the winding switching device 100, the power line 35u, and the motor 20 will be described for the U-phase as a representative example. Since the same applies for the V-phase and the W-phase, description thereof is omitted.

The power line 35u is connected to one end of the winding 21u. A power line 212u extends from the other end of the winding 21u. A power line 221u extends from one end of the winding 22u, and a power line 222u extends from the other end.

The switching circuit 104u includes semiconductor relays 111u, 112u, and 113u. The semiconductor relays 111u, 112u, and 113u are, for example, IGBTs or power MOSFETs.

The power line 35u is led into the winding switching device 100. In the winding switching device 100, the power line 35u branches off at an intermediate point and is connected to a first terminal of the semiconductor relay 111u. A second terminal of the semiconductor relay 111u is connected to a first terminal of the semiconductor relay 112u. The power line 221u extending from the winding 22u is connected to a connection point between the second terminal of the semiconductor relay 111u and the first terminal of the semiconductor relay 112u.

A second terminal of the semiconductor relay 112u is connected to a first terminal of the semiconductor relay 113u. The power line 212u extending from the winding 21u is connected to a connection point between the second terminal of the semiconductor relay 112u and the first terminal of the semiconductor relay 118u. A second terminal of the semiconductor relay 113u is connected to the power line 222u extending from the winding 22u.

When the semiconductor relays 111u and 113u are in an off state and the semiconductor relay 112u is in an on state, the windings 21u and 22u are connected in series. When the semiconductor relays 111u and 118u are in an on state and the semiconductor relay 112u is in an off state, the windings 21u and 22u are connected in parallel.

Signal lines extending from the control circuit 103u are respectively connected to the gate terminals of the semiconductor relays 111u, 112u, and 113u.

The power lines 212u, 221u, and 222u extend from the motor 20 and are led into the winding switching device 100. A current sensor 101u is attached to the power line 221u. However, the current sensor 101u may be attached to the power line 35u, 212u, or 222u instead of the power line 221u. The current sensor 101u detects a U-phase current flowing through the power line 221u. The current sensor 101u is, for example, an ACCT that detects only the AC component of a current, A signal line extending from the current sensor 101u is connected to the zero crossing detection circuit 102u. A signal line that transmits an output signal of the zero crossing detection circuit 102u (hereinafter referred to as a “zero crossing detection signal”) extends from the zero crossing detection circuit 102u to the control circuit 103u. Furthermore, a signal line extending from the control device 50 is connected to the control circuit 103u.

The zero crossing detection circuit 102u detects a zero crossing point of the measurement value of the winding current flowing through the power line 221u, which is measured by the current sensor 101u. The zero crossing detection circuit 102u is a comparator. For example, the inverting input of the comparator is set to a zero reference voltage, and the output signal of the current sensor 101u is applied to the non-inverting input. As a result, at the point in time when the AC signal output from the current sensor 101u crosses the zero reference voltage (zero crossing point), the output of the comparator changes from Low to High.

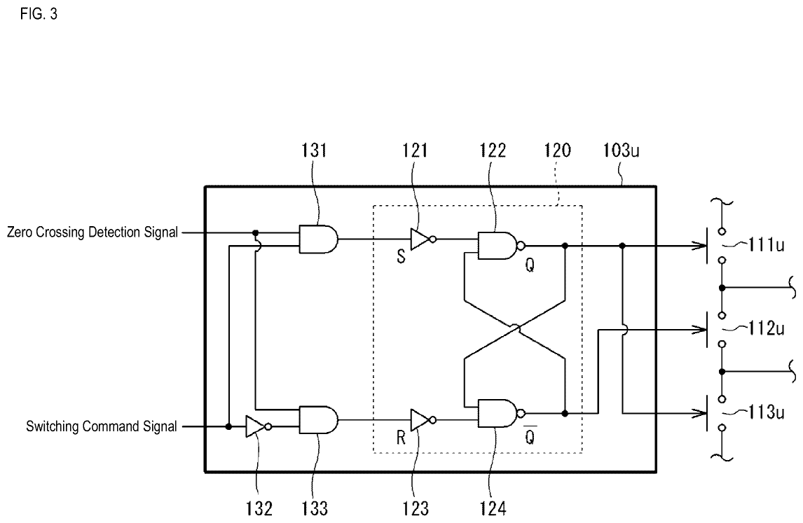

FIG. 3 is a circuit diagram showing an example of the configuration of the control circuit 103u. The control circuit 103u includes AND circuits 131 and 133, a NOT circuit 132, and a latch circuit 120. A signal line extending from the zero crossing detection circuit 102u is connected to a first input terminal of the AND circuit 131 and a first input terminal of the AND circuit 133. A signal line extending from the control device 50 is connected to a second input terminal of the AND circuit 131. Furthermore, the signal line from the control device 50 is connected to an input terminal of the NOT circuit 132. A signal line extending from the output terminal of the NOT circuit 132 is connected to a second input terminal of the AND circuit 133.

The latch circuit 120 is an RS flip-flop. The output terminal of the AND circuit 131 is connected to an input S (set) of the RS flip-flop 120. The output terminal of the AND circuit 133 is connected to an input R (reset) of the RS flip-flop 120. The RS flip-flop 120 includes two NOT circuits 121 and 123 and two NAND circuits 122 and 124. However, the RS flip-flop 120 may be constituted by two NOR circuits.

An output Q of the RS flip-flop 120 is connected to the gates of the semiconductor relays 111u and 113u. An output Q-bar of the RS flip-flop 120 is connected to the gate of the semiconductor relay 112u.

Note that the latch circuit 120 may be constituted by a D flip-flop instead of the RS flip-flop.

### 1-3. Operations of Winding Switching Device

Next, operations of the winding switching device 100 will be described. Note that, hereinafter, the operation of switching the connection state of the windings 21u and 22u for the U-phase will be described as a representative example. Since the same applies for the V-phase and the W-phase, description thereof is omitted.

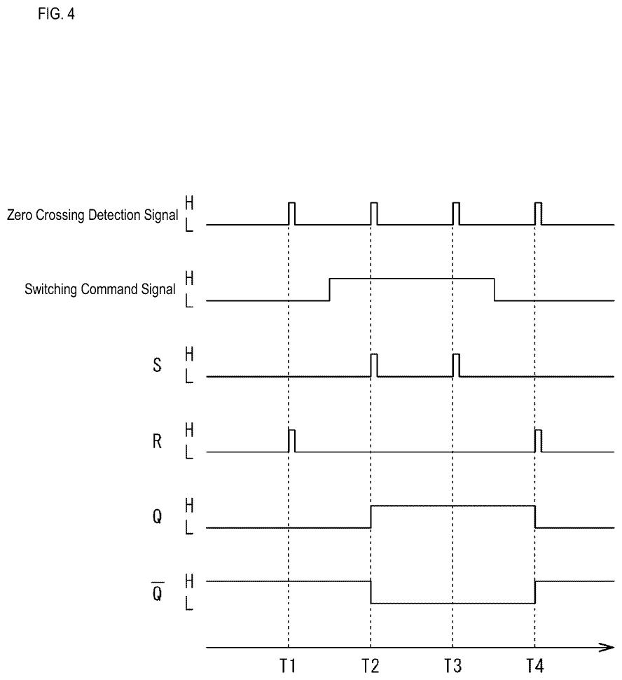

FIG. 4 is a timing chart showing an example of transition of the states of the signals of the winding switching device 100 according to the first embodiment.

The current sensor 101u measures the winding current Iu flowing through the power line 221u. The zero crossing detection circuit 102u detects the zero crossing point of the measurement value of the winding current Iu. That is, the zero crossing detection signal output from the zero crossing detection circuit 102u is Low when the winding current Iu is not zero, and is High at the point in time when the winding current Iu becomes zero. In FIG. 4, the zero crossing detection signal is normally Low and is High at times T1, T2, T3, and T4.

When the windings 21u, 22u, 21v, 22v, 21w, and 22w of the motor 20 are connected in series, the control device 50 sets the value of the switching command signal to Low, and when the windings 21u, 22u, 21v, 22v, 21w, and 22w are connected in parallel, the control device 50 sets the value of the switching command signal to High. In FIG. 4, the switching command signal is initially Low and changes to High at a point in time between times T1 and T2, The switching command signal changes to Low again at a point in time between times T3 and T4.

The zero crossing detection signal and the switching command signal are input to the AND circuit 131. The AND circuit 131 outputs Low when the zero crossing detection signal and the switching command signal are a combination of (Low, Low), (Low, High), or (High, Low). The AND circuit 131 outputs High when the zero crossing detection signal and the switching command signal are a combination of (High, High). That is, Low is normally input to S of the RS flip-flop 120, and High is input when a zero crossing point of the winding current Iu is detected and a parallel connection command for the windings 21u, 22u, 21v, 22v, 21w, and 22w is given. In FIG. 4, at times T2 and T3, the input signal of S is High.

The zero crossing detection signal and an inverted signal of the switching command signal (the output signal of the NOT circuit 132) are input to the AND circuit 133. The AND circuit 133 outputs Low when the zero crossing detection signal and the switching command signal are a combination of (Low, Low), (Low, High), or (High, High). The AND circuit 133 outputs High when the zero crossing detection signal and the switching command signal are a combination of (High, Low). That is, Low is normally input to R of the RS flip-flop 120, and High is input when a zero crossing point of the winding current Iu is detected and a series connection command for the windings 21u, 22u, 21v, 22v, 21w, and 22w is given. In FIG. 4, the input signal of R is High at times T1 and T4.

The RS flip-flop 120 holds the previous output values of Q and Q-bar when the inputs S and R are Low and Low. In the RS flip-flop 120, when the inputs S and R are Low and High, Q and Q-bar output Low and High, and when the inputs S and Rare High and Low, Q and Q-bar output High and Low. In the RS flip-flop 120, a combination in which the inputs S and R are High and High is prohibited.

In the example of FIG. 4, Q is Low and Q-bar is High until time T2. Accordingly, until time T2, the semiconductor relays 111u and 113u are in the off state, and the semiconductor relay 112u is in the on state. For this reason, the windings 21u and 22u are connected in series.

When time T2 arrives, Q changes from Low to High, and Q-bar changes from High to Low. Accordingly, the semiconductor relays 111u and 113u change from the off state to the on state, and the semiconductor relay 112u changes from the on state to the off state. For this reason, the connection state of the windings 21u and 22u switches from a series connection state to a parallel connection state.

From time T2 to T4, Q is High and Q-bar is Low. Therefore, from time T2 to time T4, the semiconductor relays 111u and 113u maintain the on state, and the semiconductor relay 112u maintains the off state. For this reason, the windings 21u and 22u are maintained in the parallel connection state, When time T4 arrives, Q changes from High to Low, and Q-bar changes from Low to High. Accordingly, the semiconductor relays 111u and 113u change from the on state to the off state, and the semiconductor relay 112u changes from the off state to the on state. For this reason, the connection state of the windings 21u and 22u switches from the parallel connection state to the series connection state.

From time T4 onwards, Q is Low and Q-bar is High. Accordingly, until time T2, the semiconductor relays 111u and 113u maintain the off state, and the semiconductor relay 112u maintains the on state. For this reason, the windings 21u and 22u are maintained in the series connection state.

As described above, the connection state of the windings 21u, 22u, 21v, 22v, 21w, and 22w can be switched between the series connection state and the parallel connection state at the timing of the zero crossing points of the winding currents Iu, Iv, and Iw. Accordingly, the occurrence of a surge voltage is suppressed. Furthermore, there is no need for complex processing to specify the period during which the winding currents Iu, Iv, and Iw are less than or equal to a predetermined value, and the winding switching device 100 can be formed without using a processor such as a CPU, FPGA, or ASIC.

### 2. Second Embodiment

The winding switching device of the second embodiment switches the connection state of a plurality of windings of a motor between a full connection state in which all of the plurality of windings are connected, and a partial connection state in which some of the plurality of windings are connected.

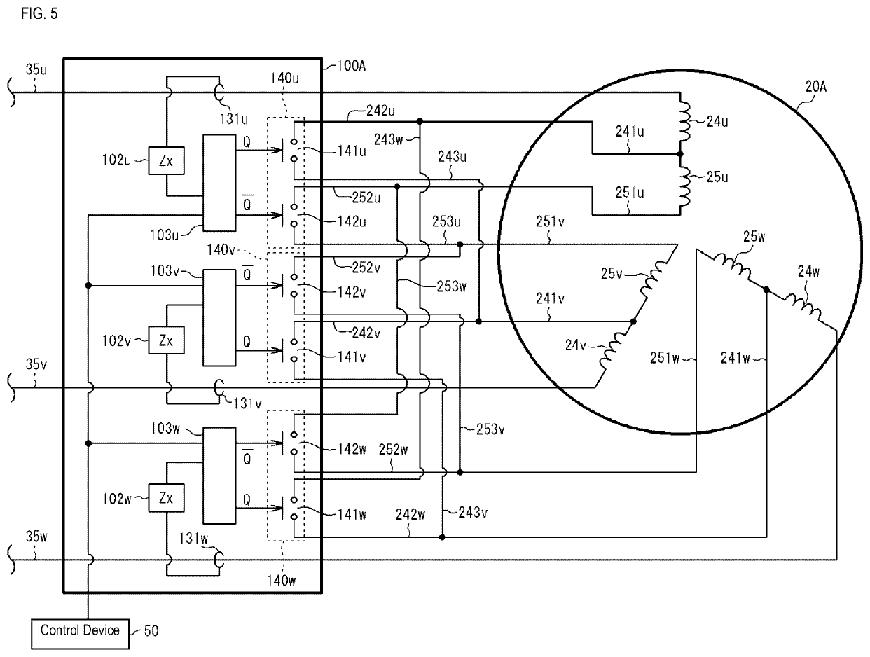

FIG. 5 is a circuit diagram showing an example of a configuration of a winding switching device according to a second embodiment. A motor 20A includes a plurality of windings 24u, 25u, 24v, 25v, 24w, and 25w. The windings 24u and 25u correspond to a U-phase, the windings 24v and 25v correspond to a V-phase, and the windings 24w and 25w correspond to a W-phase. However, the number of windings for each phase is not limited to two, and may be three or more.

A winding switching device 100A switches the connection state of the windings 24u, 25u, 24v, 25v, 24w, and 25w for each phase between a full connection state and a partial connection state. The winding switching device 100A includes current sensors 131u, 131v, and 131w, zero crossing detection circuits 102u, 102v, and 102w, control circuits 103u, 103v, and 103w, and switching circuits 140u, 140v, and 140w.

The zero crossing detection circuits 102u, 102v, and 102w detect zero crossing points of the measurement values of the current sensors 131u, 131v, and 131w. The configuration of the zero crossing detection circuits 102u, 102v, and 102w is similar to that of the first embodiment, and therefore description thereof is omitted.

The switching circuits 140u, 140v, 140w switch the connection state of the windings 24u, 25u, 24v, 25v, 24w, 25w between the full connection state and the partial connection state when the zero crossing detection circuits 102u, 102v, and 102w detect a zero crossing point. The switching circuits 140u, 140v, and 140w are an example of a switching unit. The full connection state is an example of a first connection state, and the partial connection state is an example of a second connected state.

A power line 35u is connected to one end of the winding 24u. The other end of the winding 24u and one end of the winding 25u are connected to each other, and a power line 241u extends from an intermediate point between the windings 24u and 25u. The power line 241u branches into power lines 242u and 243w. A power line 251u extends from the other end of the winding 25u. The power line 251u branches into power lines 252u and 253w.

A power line 35v is connected to one end of the winding 24v. The other end of the winding 24v and the one end of the winding 25v are connected to each other, and a power line 241v extends from an intermediate point between the windings 24v and 25v. The power line 241v branches into power lines 242v and 248u. A power line 251v extends from the other end of the winding 25v. The power line 251v branches into power lines 252v and 253u.

A power line 35w is connected to one end of the winding 24w. The other end of the winding 24w and one end of the winding 25w are connected to each other, and a power line 241w extends from an intermediate point between the windings 24w and 25w. The power line 241w branches into power lines 242w and 243v. A power line 251w extends from the other end of the winding 25w. The power line 251w branches into power lines 252w and 253v.

The switching circuit 140u includes semiconductor relays 141u and 142u. The switching circuit 140v includes semiconductor relays 141v and 142v. The switching circuit 140w includes semiconductor relays 141w and 142w. The semiconductor relays 141u, 142u, 141v, 142v, 141w, and 142w are, for example, IGBTs or power MOSFETs.

In the switching circuit 140u, a first terminal of the semiconductor relay 141u is connected to the power line 242u, and a second terminal of the semiconductor relay 141u is connected to the power line 243u. A first terminal of the semiconductor relay 142u is connected to the power line 252u, and a second terminal of the semiconductor relay 142u is connected to the power line 253u. The connection relationships of the switching circuits 140v and 140w are similar to that of the switching circuit 140u, and therefore description thereof is omitted.

When the semiconductor relays 141u, 141v, and 141w are in the off state and the semiconductor relays 142u, 142v, and 142w are in the on state, the full connection state is entered in which all of the windings 24u, 25u, 24v, 25v, 24w, and 25w are connected. When the semiconductor relays 141u, 141v, and 141w are in the on state and the semiconductor relays 142u, 142v, and 142w are in the off state, the partial connection state is entered in which only the windings 24u, 24v, and 24w are connected among the windings 24u, 25u, 24v, 25v, 24w, and 25w.

The power line 35u is led into the winding switching device 100A. The current sensor 131u is attached to the power line 35u. The current sensor 131u detects a U-phase current flowing through the power line 35u. The current sensor 131u is, for example, an ACCT that detects only the AC component of a current. A signal line extending from the current sensor 131u is connected to the zero crossing detection circuit 102u. The same applies for the V-phase and the W-phase as well.

An output Q of an RS flip-flop 120 of the control circuit 103u is connected to the gate of the semiconductor relay 141u. An output Q-bar of the RS flip-flop 120 is connected to the gate of the semiconductor relay 142u. The same applies for the V-phase and the W-phase as well.

Other configurations of the winding switching device 100A according to the second embodiment are similar to those of the winding switching device 100 according to the first embodiment, and therefore identical components are denoted by identical reference numerals and description thereof is omitted.

In the second embodiment, the control device 50 sets the value of the switching command signal to Low when the windings 24u, 25u, 24v, 25v, 24w, and 25w of the motor 20 are to be put in the full connection state, and sets the value of the switching command signal to High when the windings 24u, 25u, 24v, 25v, 24w, and 25w are to be put in the partial connection state.

When the windings are in the full connection state, the output Q becomes Low and the output Q-bar becomes High at the timing when the zero crossing detection signal and the switching command signal both become High. Accordingly, the semiconductor relay 141u changes from the on state to the off state, and the semiconductor relay 142u changes from the off state to the on state. The same applies for the V-phase and the W-phase as well. For this reason, the connection state of the windings 24u, 25u, 24v, 25v, 24w, and 25w is switched from a full connection state to a partial connection state.

When the windings are in the partial connection state, the zero crossing detection signal becomes High and the switching command signal becomes Low, and at that timing, the output Q becomes High and the output Q-bar becomes Low. Accordingly, the semiconductor relay 141u changes from the off state to the on state, and the semiconductor relay 142u changes from the on state to the off state. The same applies for the V-phase and the W-phase as well. For this reason, the connection state of the windings 24u, 25u, 24v, 25v, 24w, and 25w is switched from the partial connection state to the full connection state.

As described above, the connection state of the windings 21u, 22u, 21v, 22v, 21w, and 22w can be switched between the full connection state and the partial connection state at the timing of the zero crossing points of the winding currents Iu, Iv, and Iw.

### 3. Third Embodiment

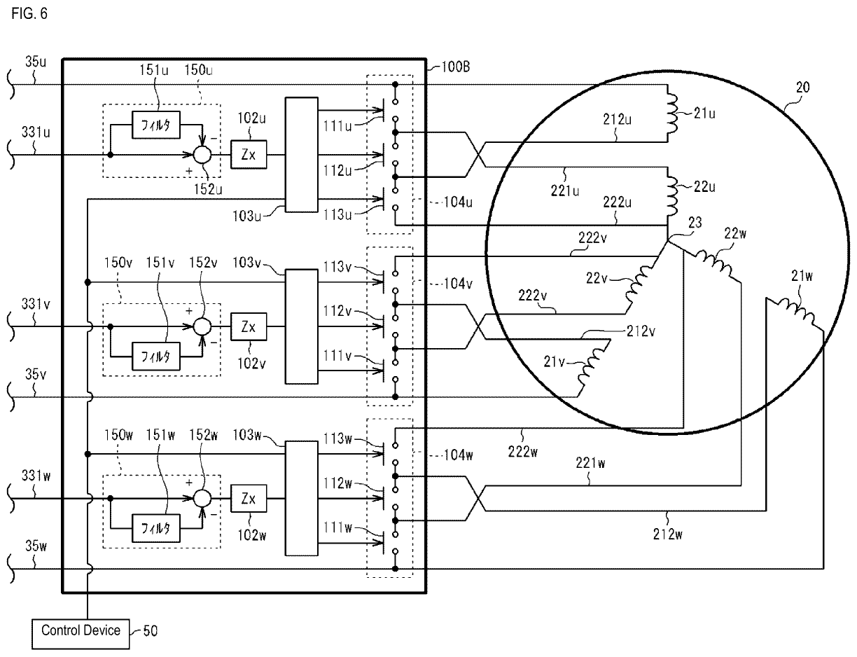

FIG. 6 is a circuit diagram showing an example of a configuration of a winding switching device according to a third embodiment. In a winding switching device 100B according to the third embodiment, signal lines 331u, 331v, and 331w extending from current sensors 33u, 33v, and 38w arranged in a power converter 30 are connected to zero crossing detection circuits 102u, 102v, and 102w.

In a more specific example, the winding switching device 100B includes correction circuits 150u, 150v, and 150w that remove DC components from the output signals of the current sensors 33u, 33v, and 33w. The correction circuits 150u, 150v, and 150w are examples of correction units.

Hereinafter, the configuration of the correction circuit 150u for the U-phase will be described below as a representative example. Since the same applies for the V-phase and W-phase, description thereof is omitted.

The signal line 331u extending from the power converter 30 is led into the winding switching device 100B. That is, the signal line 331u extending from the current sensor 33u is directly led into the winding switching device 100B without passing through a signal processing circuit or the like on the way. In the winding switching device 100B, the signal line 331u branches, and one of the signal lines is connected to a first input terminal of a subtraction circuit 152u. The other signal line is connected to an input terminal of a filter 151u. A signal line extends from an output terminal of the filter 151u and is connected to a second input terminal of the subtraction circuit 152u. A signal line extends from an output terminal of the subtraction circuit 152u and is connected to the zero crossing detection circuit 102u.

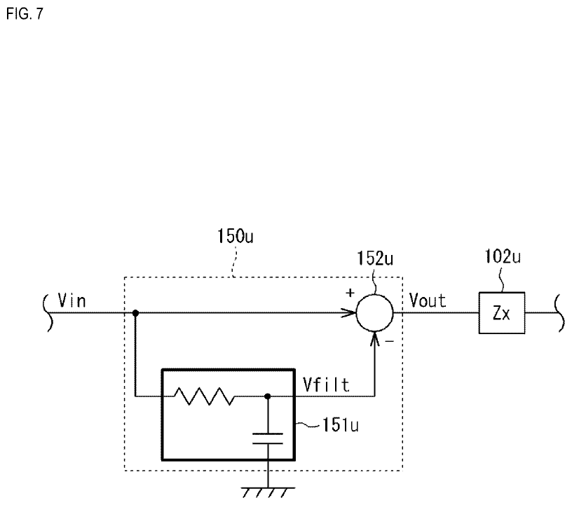

FIG. 7 is a circuit diagram showing an example of the configuration of the correction circuit. The filter 151u is a low pass filter including a resistor and a capacitor. The filter 151u removes, from a voltage signal Vin output from the current sensor 33u, a frequency component higher than or equal to a threshold that is lower than the frequency of the winding currents Iu, Iv, Iw at a point in time when the connection state of the windings of the motor 20 is switched. The filter 151u outputs a voltage signal Vfilt obtained by removing the above-described frequency component from the input voltage signal Vin.

The subtraction circuit 152u receives the voltage signal Vin from the current sensor 33u and the voltage signal Vfilt from the filter 151u, and outputs a differential voltage Vout between Vin and Vfilt.

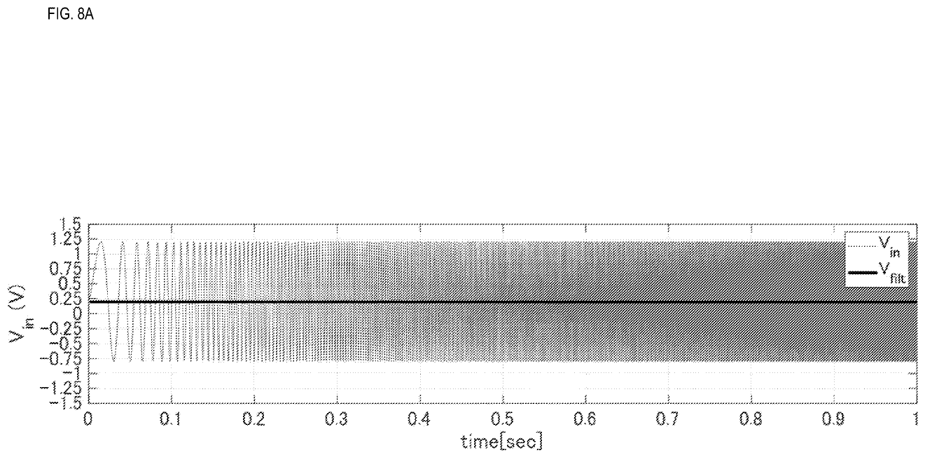

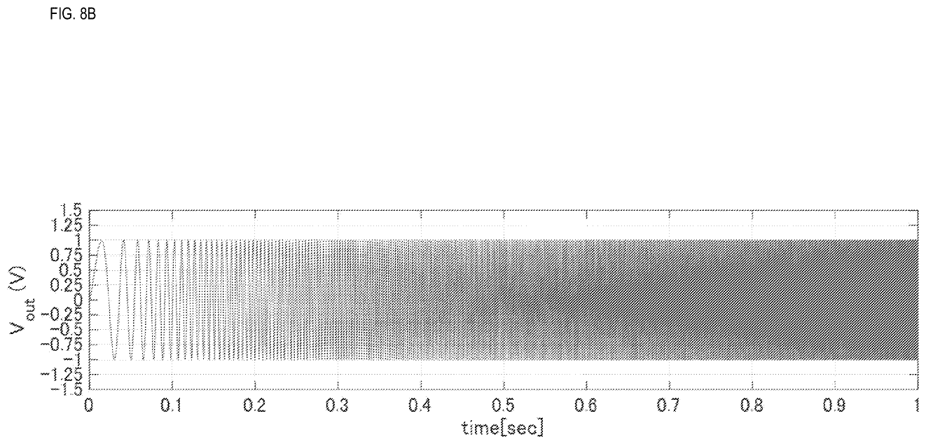

FIG. 8A is a graph showing the waveforms of the voltage signal Vin from the current sensor 33u and the voltage signal Vfilt from the filter 151u. In FIG. 8A, the vertical axis represents voltage and the horizontal axis represents time. The voltage signal Vin output from the current sensor 33u includes an AC component corresponding to the U-phase and a DC component. Accordingly, the voltage signal Vin exhibits a waveform in which an alternating current having the same frequency as the AC current corresponding to the U-phase is offset by the DC component described above. In the example of FIG. 8A, the AC waveform is offset by a DC component of 0.2 V.

The filter 151u removes the AC component from the voltage signal Vin. Accordingly, the voltage signal output from the filter 151u is the above-mentioned DC component. That is, in the example of FIG. 8A, Vfilt is a DC voltage of 0.2 V.

FIG. 8B is a graph showing the waveform of a voltage signal from the subtraction circuit 152u. The subtraction circuit 152u subtracts Vfilt from the voltage signal Vin output from the current sensor 33u. Accordingly, the voltage signal Vout output from the subtraction circuit 152u is a signal in which the offset amount from Vin has been corrected to zero, that is, an AC voltage signal that does not include a DC component.

With the above-described configuration, the zero crossing detection circuit 102u can detect the zero crossing point in the U-phase winding current Iu without being affected by the DC component included in the output voltage of the current sensor 33u.

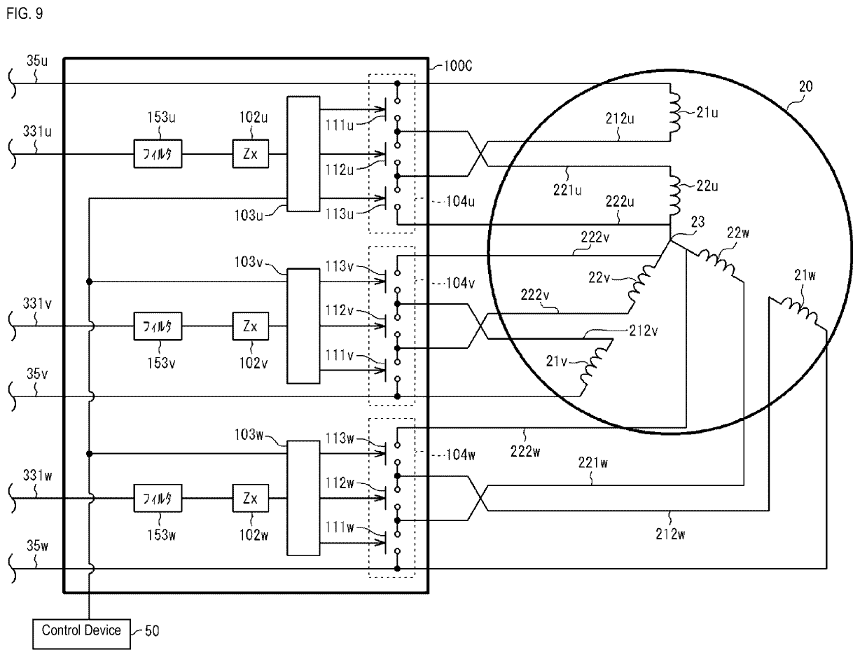

Note that the configuration of the correction circuit 150u is not limited to the above description. FIG. 9 is a circuit diagram showing a modified example of the configuration of the winding switching device according to the third embodiment. In the modified example shown in FIG. 9, the correction circuits are filters 153u, 153v, and 153w. The filters 153u, 158v, and 153w are high-pass filters having a feature of passing only frequency components greater than or equal to a threshold that is lower than the frequency of the winding currents Iu, Iv, and Iw at the point in time when the connection state of the windings of the motor 20 is switched. With this configuration as well, the DC components can be removed from the output signals of the current sensors 33u, 33v, and 33w.

### 4. Fourth Embodiment

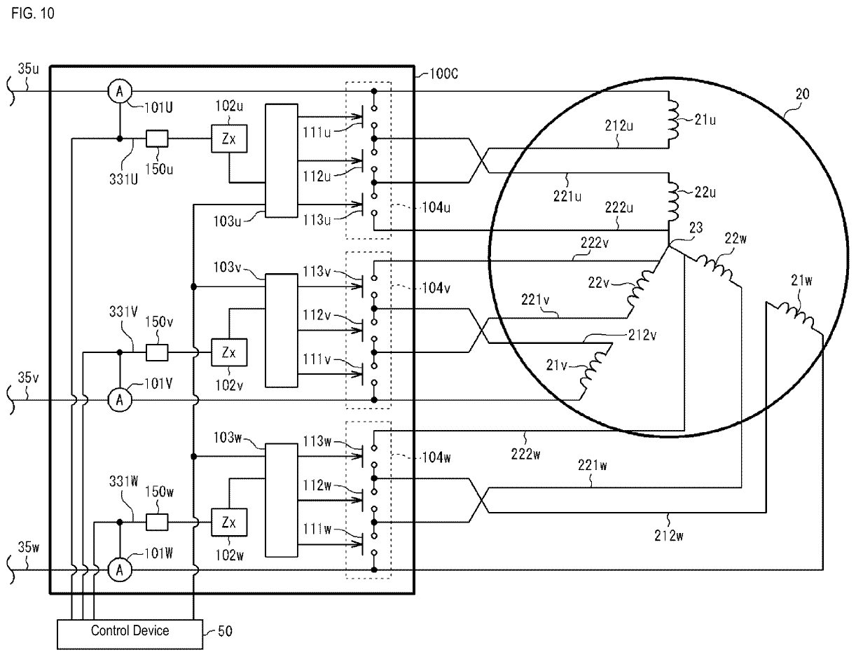

FIG. 10 is a circuit diagram showing an example of a configuration of a winding switching device according to a fourth embodiment. A winding switching device 100C according to the fourth embodiment includes current sensors 101U, 101V, and 101W.

The current sensor 101U is attached, for example, to a power line 35u that is led into the winding switching device 100C. However, the current sensor 101U may be attached to a power line 211u, 212u, or 222u instead of the power line 35u. The current sensor 101U detects a U-phase current flowing through the power line 35u. Similarly, the current sensors 101V and 101W are attached to power lines 35v and 35w. The current sensors 101U, 101V, and 101W can detect the current value as well as the DC components and the AC components of the current flowing through the power lines 35u, 35v, and 35w. The current sensor 101U is, for example, a DC current transformer (DCCT) or a shunt resistor.

The signal lines 331U, 331V, and 331W extending from the current sensors 101U, 101V, and 101W are connected to zero crossing detection circuits 102u, 102v, and 102w.

In a more specific example, the winding switching device 100C includes correction circuits 150u, 150v, and 150w that remove DC components from the output signals of the current sensors 101U, 101V, and 101W. The correction circuits 150u, 150v, and 150w are the same as the correction circuits 150u, 150v, and 150w described in the second embodiment.

Each of the signal lines 331U, 331V, and 331W branches off at an intermediate portion thereof, and the branched ends are connected to the control device 50. The control device 50 receives output signals from the current sensors 101U, 101V, and 101W. In this embodiment, the current sensors 33u, 33v, and 33w provided in the power converter 30 are omitted.

The control device 50 performs feedback control of the motor 20 based on the current values detected by the current sensors 101U, 101V, and 101W. That is, the control device 50 determines the voltage values to be applied to windings 21u, 22u, 21v, 22v, 21w, and 22w based on the current values of the U-phase, V-phase, and W-phase currents input to the motor 20, and turns on and off switches 31u, 32u, 31v, 32v, 31w, and 32w through PWM control in accordance with the determined voltage values. That is, in this embodiment, the current sensors 101U, 101V, and 101W are also used in the control of the power converter 30. This allows the number of current sensors in the entire winding switching system to be reduced.

### 4. Supplementary Note

The embodiments disclosed herein are exemplary in all respects and are not restrictive. The scope of the present invention is indicated not by the above-described embodiments, but by the claims, and encompasses meanings equivalent to the claims and all modifications within the scope thereof.

1. A winding switching device for switching a connection state of a plurality of windings of a motor capable of switching the connection state of the plurality of windings between a first connection state and a second connection state, the winding switching device comprising:
a detection circuitry configured to detect a zero crossing point of a measurement value of a current sensor configured to measure current flowing through a winding of the windings; and
a switching circuitry configured to switch the connection state of the plurality of windings between the first connection state and the second connection state at a timing at which the detection circuitry detects the zero crossing point.

2. The winding switching device according to claim 1,
wherein the motor is a multi-phase AC motor,
the detection circuitry detects the zero crossing point for each phase, and
the switching circuitry switches the connection state of the plurality of windings between the first connection state and the second connection state for each phase.

3. The winding switching device according to claim 1,
wherein the detection circuitry compares an output voltage from the current sensor and a reference voltage corresponding to the output voltage of the current sensor when the current flowing through the winding is zero, and detects, as a zero crossing point, a point in time when the output voltage from the current sensor and the reference voltage coincide with each other.

4. The winding switching device according to claim 3, wherein the detection circuitry is a comparator.

5. The winding switching device according to claim 1, wherein the detection circuitry shares the current sensor with control of a power converter configured to convert a DC voltage output from a battery into an AC voltage and supply the AC power to the motor.

6. The winding switching device according to claim 5, wherein the current sensor is disposed in the winding switching device.

7. The winding switching device according to claim 6, wherein the current sensor is an AC current transformer.

8. The winding switching device according to claim 5, wherein the current sensor is disposed in the power converter, and
a signal line extending from the current sensor is connected to the detection circuitry.

9. The winding switching device according to claim 8, further comprising:
a correction circuitry configured to remove a DC component from the output signal of the current sensor,
wherein the detection circuitry detects a zero crossing point of the output signal of the current sensor from which the DC component has been removed by the correction circuitry.

10. A winding switching system comprising:
a motor capable of switching a connection state of a plurality of windings between a first connection state and a second connection state;
a power converter configured to convert DC power output from a battery into AC power and supply the AC power to the motor; and
a winding switching device for switching the connection state of the plurality of windings,
wherein the winding switching device includes:
a detection circuitry configured to detect a zero crossing point of a measurement value of a current sensor configured to measure current flowing through a winding of the windings; and
a switching circuitry configured to switch the connection state of the plurality of windings between the first connection state and the second connection state at a timing when the detection circuitry detects the zero crossing point.
